(19) United States
(12) Patent Application Publication
(10) Pub. No.: US 2015/0204625 A1
(43) Pub. Date: Jul. 23, 2015

(54) HIGH TEMPERATURE HEAT TRANSFER INTERFACE

(71) Applicant: United Technologies Corporation, Hartford, CT (US)

(72) Inventors: Matthew Robert Pearson, East Hartford, CT (US); Neal R. Herring, East Hampton, CT (US)

(21) Appl. No.: 14/507,904

(22) Filed: Oct. 7, 2014

Related U.S. Application Data
(60) Provisional application No. 61/888,610, filed on Oct. 9, 2013.

(51) Int. Cl. F28F 21/08; H01L 35/30

(52) U.S. Cl. CPC F28F 21/081; H01L 35/30

(57) ABSTRACT

A thermal interface includes a first thermal component and a second thermal component. A fluid filled cushion is disposed between the first thermal component and the second thermal component, and is a thermal joint.

### CROSS-REFERENCE TO RELATED APPLICATION

This application claims priority to U.S. Provisional Application No. 61/888,610 filed on Oct. 9, 2013.

### STATEMENT REGARDING GOVERNMENT SUPPORT

This invention was made with government support under Contract No. N00014-08-C-0161 awarded by the United States Navy. The Government has certain rights in this invention.

### TECHNICAL FIELD

The present disclosure relates generally to heat transfer interfaces, and more specifically to heat transfer interfaces for use in high temperature applications.

### BACKGROUND OF THE INVENTION

Many industrial applications require thermal interfaces at a boundary between two objects, with the goal of transferring heat effectively from the first object to the second object. For lower temperature applications, such as applications where the temperatures do not exceed 200° C., multiple thermal interface materials exist, including thermal grease and thermal pads, that can significantly reduce the thermal contact resistance between two components. When operating at sufficiently high temperatures, such as temperatures exceeding 400° C., the known thermal interface materials break down.

In some existing systems operating at extremely high temperatures, a liquid metal, such as gallium-tin, is used to improve the thermal resistance between the two contacting surfaces. A thin layer of the liquid metal is applied between the surfaces, and fills micro-scale voids and imperfections, strengthening the thermal contact. Due to the nature of operating at extremely high temperatures, however, hot side components in the thermal interface frequently undergo bending, bowing, warping and creep due to thermal expansion. Thus, even if the two surfaces are in close contact and parallel during assembly, there is likely to be large voids and vapor spaces between the two components at high operating temperatures. The large voids and vapors spaces are not filled with the liquid metal and provide a poor thermal contact.

### SUMMARY OF THE INVENTION

A thermal interface according to an exemplary embodiment of this disclosure, among other possible things includes a first thermal component, a second thermal component, a fluid filled cushion disposed between the hot side component and the cold side component, and the fluid filled cushion is a thermal joint.

In a further embodiment of the foregoing thermal interface, the fluid filled cushion includes a flexible outer wall defining a cavity and a fluid disposed in the cavity.

In a further embodiment of the foregoing thermal interface, the fluid is a liquid having a high thermal conductivity.

In a further embodiment of the foregoing thermal interface, the liquid is one of a gallium-tin based liquid or an indium based liquid.

A further embodiment of the foregoing thermal interface, further includes a highly thermally conductive particulate suspended within the fluid thereby increasing a thermally conductive of the fluid.

In a further embodiment of the foregoing thermal interface, the flexible outer wall is a metal foil.

In a further embodiment of the foregoing thermal interface, a material in the fluid filled cushion is a liquid at temperatures exceeding 200 degrees centigrade, and a solid at a room temperature.

In a further embodiment of the foregoing thermal interface, a third thermal component disposed between the first thermal component and the second thermal component, a thermal joint connecting the third thermal component to the second thermal component, and the fluid filled cushion thermally connecting the first thermal component to the third thermal component.

In a further embodiment of the foregoing thermal interface, the thermal joint is compressible.

In a further embodiment of the foregoing thermal interface, the third thermal component is a thermoelectric component.

In a further embodiment of the foregoing thermal interface, the thermal joint is a silicone pad.

In a further embodiment of the foregoing thermal interface, the first thermal component is a first shape at room temperature and a thermally deformed shape at an operating temperature of the thermal interface.

In a further embodiment of the foregoing thermal interface, the fluid filled cushion maintains thermal contact with the first thermal component while the thermal interface is at the operating temperature.

In a further embodiment of the foregoing thermal interface, the thermal interface is loaded via a loading component, and the loading component is compressible such that the second thermal component is maintained in thermal contact with the fluid filled cushion during operation of the thermal interface.

In a further embodiment of the foregoing thermal interface, the flexible outer wall includes a plurality of inward facing protrusions extending from the flexible outer wall into the cavity.

A method for transferring heat according to an exemplary embodiment of this disclosure, among other possible things includes generating heat at a first thermal interface component such that a component of a heat transfer interface undergoes thermal deformation, maintaining contact between a fluid filled cushion and the first thermal interface component during thermal deformation, maintaining contact between a second thermal interface component and the fluid filled cushion such that a thermal pathway is provided from the first thermal interface component and the second thermal interface component.

In a further embodiment of the foregoing method, the second thermal interface component is a thermoelectric device and passing heat through the second thermal interface components generates electrical energy.

In a further embodiment of the foregoing method, the first thermal interface component is an electronic component generating heat and the second thermal interface component is a heat sink.

In a further embodiment of the foregoing method, the step of maintaining contact between the fluid filled cushion and the first thermal interface component during thermal deformation includes allowing a flexible wall of the fluid filled cushion to flex complimentary to the thermal deformation, thereby maintaining contact between the first thermal interface component and the second thermal interface component.

A waste heat recovery system for a turbine engine according to an exemplary embodiment of this disclosure, among other possible things includes a gas turbine engine component operable to generate waste heat, a thermal interface connected to the gas turbine engine component, the thermal interface including a first thermal component, a second thermal component, a fluid filled cushion disposed between the first thermal component and the second thermal component, the fluid filled cushion is a thermal joint, and the second thermal component is a thermoelectric device.

The foregoing features and elements may be combined in any combination without exclusivity, unless expressly indicated otherwise.

These and other features of the present invention can be best understood from the following specification and drawings, the following of which is a brief description.

### BRIEF DESCRIPTION OF THE DRAWINGS

FIG. 1A schematically illustrates a high heat thermal interface at room temperature.

FIG. 1B schematically illustrates the high heat thermal interface of FIG. 1A at an operating temperature.

FIG. 2A schematically illustrates another example high heat thermal interface at room temperature.

FIG. 2B schematically illustrates the example high heat thermal interface of FIG. 2A at an operating temperature.

FIG. 3A schematically illustrates another example high heat thermal interface at room temperature.

FIG. 3B schematically illustrates the example high heat thermal interface of FIG. 3A at an operating temperature.

FIG. 4 schematically illustrates a first alternate configuration high heat thermal interface.

FIG. 5 schematically illustrates a second alternate configuration high heat thermal interface.

FIG. 6 schematically illustrates a fluid filled cushion for a thermal contact.

FIG. 7 schematically illustrates another example high heat interface.

FIG. 8 schematically illustrates an example flexible material.

### DETAILED DESCRIPTION OF AN EMBODIMENT

FIG. 1A schematically illustrates a high heat thermal interface 10 for thermally connecting a hot side component 20 to a cold side component 30 at room temperature. The hot side component 20 and the cold side component 30 are generically referred to as thermal components. A fluid filled cushion 40 is positioned contacting an interface surface 22 of the hot side component 20 and an interface surface 32 of the cold side component 30. The fluid filled cushion 40 includes a flexible wall 42 that is thermally conductive. In some examples, the flexible wall 42 is a metal foil with a thickness of between 0.0005 inches to 0.010 inches (0.00127 centimeters to 0.0254 centimeters). Contained within the flexible wall 42 is a highly thermally conductive fluid 44, such as a liquid metal form of gallium-tin or indium. In some examples, the fluid 44 is a non-compressible fluid. In these examples, the volume of the fluid 44 contained within the fluid filled cushion 40 is maintained constant through all operation modes of the thermal interface 10.

With continued reference to FIG. 1A, and with like elements receiving like numerals, FIG. 1B illustrates the high heat thermal interface 10 of FIG. 1A during standard high heat operating conditions. By way of example, standard high heat operating conditions can exceed 400° C. in some examples, and can be in the range of 200° C. to 400° C. in other examples. As a result of the extreme temperature at standard operating conditions, the hot side component 20 can warp or bow, resulting in the curved shape illustrated in FIG. 1B. Alternate warping profiles or curvatures can also occur, and the singular bow illustrated is for exemplary purposes only. As a result of the flexible nature of the fluid filled cushion 40, the interface surface 22 of the hot side component 20 and the interface surface 32 of the cold side component 30 cause the flexible surface 44 of the fluid filled cushion 40 to flex and change shape, thereby maintaining contact with the fluid filled cushion 40, and minimizing degradation of the heat transfer when one of the components 20, 30 is warped due to elevated temperatures. In some examples, the hot side component 20 and the cold side component 30 are pushed together via an outside component, thereby further maintaining the thermal contact.

In each of the examples of FIGS. 1A and 1B, heat transfers along a heat transfer path 50 from the hot side component 20 to the fluid filled cushion 40, and then into the cold side component 30. Once in the cold side component 30 the heat can be dissipated using any known means, or the cold side component 30 can be cooled using any known means. In some examples, the cold side component 30 is a heat sink and is cooled via any known heat sink cooling means.

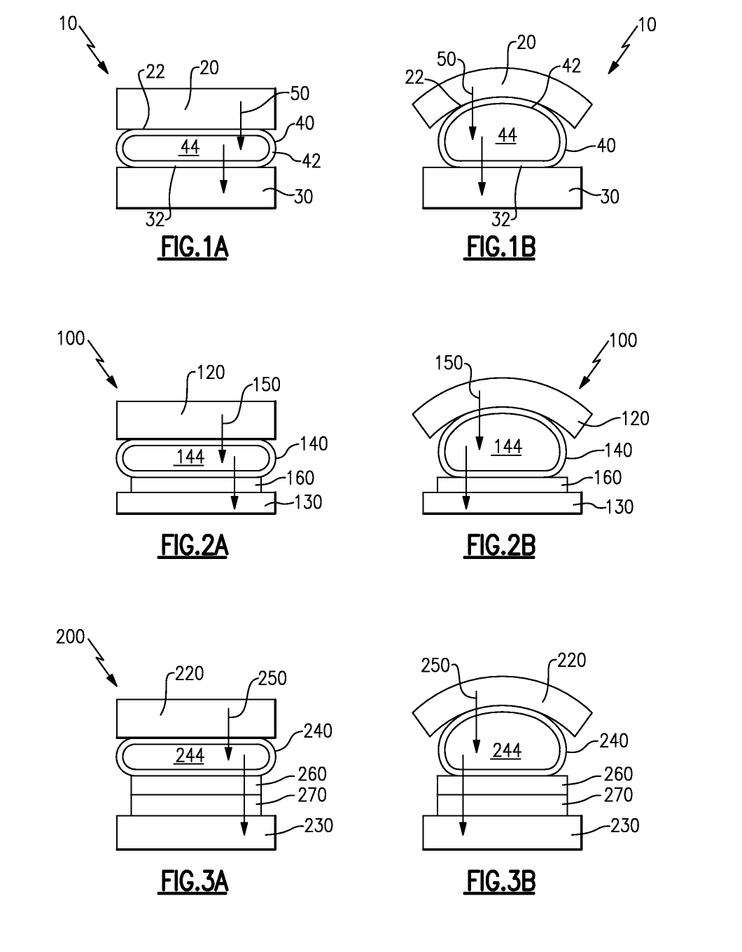

With continued reference to FIGS. 1A and 1B, and with like numerals indicating like elements, FIGS. 2A and 2B illustrate an alternate example thermal interface 100 including an additional thermoelectric component 160 disposed between a cold side component 130 and a fluid filled cushion 140 in a room temperature assembly (FIG. 2A) and at a high operating temperature (FIG. 2B). The additional thermoelectric component 160 is disposed between the fluid filled cushion 140 and the cold side component 130 and uses a heat transfer path 150 across the thermoelectric component 160 to generate an electric current in the thermoelectric component 160. The thermoelectric component 160 may also experience some warping during operation. Aside from the additional inclusion of the thermoelectric component 160, the example thermal interface 100 of FIGS. 2A and 2B is the same as the thermal interface 10 of FIGS. 1A and 1B.

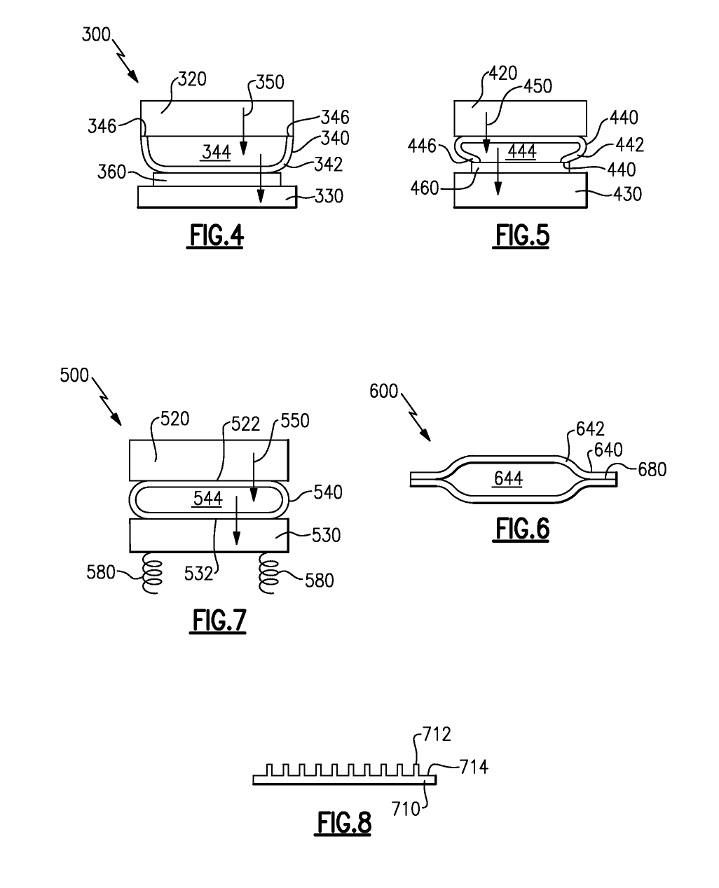

With continued reference to FIGS. 1A, 1B, 2A and 2B, and with like numerals indicating like elements, FIGS. 3A and 3B illustrate a further example thermal interface 200, including all the features of the thermal interface 100 of FIGS. 2A and 2B, with FIG. 3A corresponding to room temperature, and FIG. 3B corresponding to an operating temperature. The example of FIGS. 3A and 3B includes a secondary interface 270, such as a silicon pad, liquid metal, or thermal grease. The secondary interface 270 is positioned between the thermoelectric component 260 and the cold side component 230 and facilitates heat transfer at the contact.

In some examples, the thermoelectric component 260 is fragile. In such examples, the secondary interface 270 is a compressible thermal interface, such as a silicon pad. During operation the warping and bowing of the hot side component 220 causes shifting in the thermal interface 200 and, the shifting is translated to and absorbed by the compressible secondary interface 270, rather than the thermoelectric component 260 thereby protecting the thermoelectric component 260.

Referring collectively to the examples of FIGS. 2A, 2B, 3A, and 3B, the heat transfer paths 150, 250 are illustrated as passing from a hot side component 120, 220 through thermal contacts into a cold side component 130. In alternate configurations, however, the thermoelectric component 160 can be the source of the heat, or an alternate heat generating component can be positioned in place of the thermoelectric component 160, 260. In these examples, heat originates in the thermoelectric component 160, 260 and passes outwards through the fluid filled cushion 140, 240 and the secondary interface 270. In a further modification of this example, the secondary interface 270 is a fluid filled cushion similar to the fluid filled cushion 140, 240 adjacent the hot side component 120, 220, thereby providing a high heat tolerance interface at both heat transfer surfaces of the thermoelectric component 160, 260.

With continued reference to FIGS. 1A, 1B, 2A, 2B, 3A and 3B, and with like numerals indicating like elements, FIG. 4 illustrates an example construction of a fluid filled cushion 340 in an alternate example thermal interface 300. As with the examples of FIGS. 2A and 2B, the thermal interface 300 utilizes a fluid filled cushion 340 at an interface between a thermoelectric component 360 and a hot side component 320. Instead of the separate fluid filled cushion 240 positioned between the hot side component 220 and the thermoelectric component 260 (as illustrated in the example of FIGS. 2A and 2B), the fluid filled cushion 340 of the example of FIG. 4 is constructed integral to the hot side component 320. The flexible cushion wall 340 is connected at edges 346 to the hot side component 320 and a high heat thermally conductive fluid 344 is positioned within the void formed between the flexible wall 342 of the fluid filled cushion 340 and the hot side component 320. The edges of the flexible wall 342 are sealed to the hot side component 320 via any known bonding technique.

With continued reference to FIGS. 1A, 1B, 2A, 2B, 3A, 3B and 4, and with like numerals indicating like elements, FIG. 5 illustrates an alternate example construction of a fluid filled cushion 440 is illustrated. As with the example of FIG. 4, the fluid filled cushion 440 of FIG. 5 is constructed from a flexible wall 442 attached at edges 446 to the thermoelectric component 460. The flexible wall 442 and the thermoelectric component 260 form a void that is filled with a highly thermally conductive fluid 444. Thus, the fluid filled cushion 440 is integral to the thermoelectric component 460.

Referring now to both FIGS. 4 and 5, the flexible wall 342, 442 in each example is bonded at the edges 346, 446, to the corresponding component 320, 460 using any known bonding means that will maintain a seal and a bond at extremely high temperatures. By creating the fluid filled cushion 340, 440 integral to one of the components of the thermal interface 300, 400, the amount of material required to create the fluid filled cushion 340, 440 is reduced and the possibility of the integral component 320, 460 separating from the fluid filled cushion 340, 440 is removed.

FIG. 6 illustrates an alternate example construction of a fluid filled cushion 600 that can be utilized in the example thermal interfaces 10, 100, 200, 500 of FIGS. 1A, 1B, 2A, 2B, 3A, 3B and 7, with like numerals indicating like elements. The alternate construction utilizes two independent flexible wall layers 640 and bonds the edges of the flexible wall layers 640 together at a bond surface 690. After a portion of the edges have been bonded to each other, a high heat thermally conductive fluid 644 is positioned within a void created between the flexible walls 640 and the final edge is then sealed. Alternately, the same arrangement can be constructed using a single flexible wall 640 folded over and having it's edges bonded to each other.

As described above with regards to the secondary interface 270 of FIGS. 3A and 3B, the flexible wall 242 shifts and flexes along with the thermal warping of the hot side component 220. This shifting can cause, in some applications, additional separation between the hot side component 220 and the fluid filled cushion 240.

With continued reference to FIGS. 1A, 1B, 2A, 2B, 3A, 3B, 4, 5 and 6 FIG. 7 illustrates an example high heat thermal interface that addresses this shifting without the inclusion of a flexible pad as a secondary interface 270.

The high heat thermal interface 500 of FIG. 7 includes a hot side component 520, a cold side component 530 and a fluid filled cushion 540 arranged in a similar fashion to the high heat thermal interface illustrated in FIGS. 1A and 1B. Contacting the cold side component 530 is a loading component 580. While illustrated as a pair of coil springs, the loading component 580 can be any compressible component that applies a load to the high heat thermal interface 500, thereby pressing the cold side component 530 toward the hot side component 520. The loading component 580 compresses to absorb shifting and bowing, while maintaining a load on the high heat thermal interface 500 thereby ensuring that a maximum thermal contact is maintained between a thermal contact surface 522 and the fluid filled cushion 540 and between a thermal contact surface 532 of the cold side component 530 and the fluid filled cushion 540.

Referring again to FIGS. 1A and 1B as a general example, the fluid 44 is a thermally conductive fluid that is tolerant of high heats, such as a liquid metal. In alternate examples the fluid can be a solid at room temperature, with a melting point lower than the standard operating temperatures. In this example, the fluid 44 is a solid while the hot side component 20 is in its non-thermally deformed state, and converts to a liquid as the temperatures approach operating temperature.

In yet a further example, the fluid 44 contained within the fluid filled cushion 40 can include a solid particulate to further increase the thermal conductivity. In this example, the solid particulate is suspended within the fluid 44, and the fluid filled cushion maintains the flexibility described above while taking advantage of the increased thermal conductivity of the solid particulate.

FIG. 8 illustrates an example material for creating the fluid filled cushion 40 of FIGS. 1A and 1B. The material 710 includes multiple fingers 712 protruding from one surface 714. The surface 714 is formed as the internal surface of the fluid filled cushion 40 illustrated in FIGS. 1A and 1B. The fingers provide greater surface area contacting the fluid, and further enhance heat transfer through the fluid filled cushion in a similar manner to that of the suspended particulate described above. In alternate examples, the fingers 712 can be ridges or vanes instead of fingers, and provide a similar effect.

While each of the above described aspects of the fluid filled cushion 40 and the fluid 44 are described independently, one of skill in the art having the benefit of this disclosure will understand that the features can be used independently or in combination as dictated by the particular requirements of any given application.

Referring now to the general embodiment of FIGS. 3A and 3B, one practical embodiment of the above described heat transfer interface 200 is utilized for a waste heat recovery system in an aircraft. Two potential sources of waste heat in any gas turbine engine are heat emanating from a combustor and heat from engine exhaust steam. Alternately, any turbine engine component that generates excessive heat can be utilized in the below described practical embodiment.

The hot side component 220 of the thermal interface 200 is placed against, or otherwise thermally joined to the turbine engine component generating the excess waste heat and the cold side component 230 is connected to a heat sink or other cooling device. As the heat transfers through the thermal interface from the heat generating turbine engine component to the heat sink or other cooling device, the heat passes through the thermoelectric component 260. The heat passing through the thermoelectric component 260 generates electrical currents according to known thermoelectric principles.

Depending on the magnitude of electrical energy generated by the thermoelectric component 260, the generated current can be provided to local sensors and/or engine electronics or to a general aircraft power system.

Referring now to the general embodiment of FIGS. 1A and 1B, the thermal interface 10 can be utilized in conjunction with high power electronics such as IGBT's, MOSFETs, diodes, etc. These types of high power electronics are used in “more electric aircraft” to provide power conversions from DC to AC and vice versa. It is known that the power electronics operate at extremely high temperatures and conventional thermal interfaces can be inadequate for cooling, as is described above.

By utilizing the power electronics component as the hot side component 20, and placing the fluid filled cushion 40 adjacent and contacting the hot side component, as illustrated in FIG. 1A and 1B, a high heat tolerant thermal interface can be provided. The cold side component 30 of the thermal interface 10 is connected to a heat sink allowing the heat to be dissipated in a conventional manner from the heat sink.

In a similar embodiment, fluid filled cushions 40 can be placed contacting multiple sides of the high power electronics. Each of the fluid filled cushions 40 contacts a corresponding cold side component 30, and heat dissipates through the thermal interfaces 10 as described previously.

It is further understood that any of the above described concepts can be used alone or in combination with any or all of the other above described concepts. Although an embodiment of this invention has been disclosed, a worker of ordinary skill in this art would recognize that certain modifications would come within the scope of this invention. For that reason, the following claims should be studied to determine the true scope and content of this invention.

1. A thermal interface comprising:
a first thermal component;
a second thermal component;
a fluid filled cushion disposed between said first thermal component and said second thermal component, and wherein the fluid filled cushion is a thermal joint.

2. The thermal interface of claim 1, wherein the fluid filled cushion comprises a flexible outer wall defining a cavity and a fluid disposed in said cavity.

3. The thermal interface of claim 2, wherein said fluid is a liquid having a high thermal conductivity.

4. The thermal interface of claim 3, wherein said liquid is one of a gallium-tin based liquid or an indium based liquid.

5. The thermal interface of claim 3, further comprising a highly thermally conductive particulate suspended within said fluid thereby increasing a thermally conductive of the fluid.

6. The thermal interface of claim 2, wherein said flexible outer wall is a metal foil.

7. The thermal interface of claim 1, wherein a material in said fluid filled cushion is a liquid at temperatures exceeding 200 degrees centigrade, and a solid at a room temperature.

8. The thermal interface of claim 1, further comprising
a third thermal component disposed between said first thermal component and said second thermal component;
a thermal joint connecting said third thermal component to said second thermal component; and
said fluid filled cushion thermally connecting said first thermal component to said third thermal component.

9. The thermal interface of claim 8, wherein the thermal joint is compressible.

10. The thermal interface of claim 8, wherein the third thermal component is a thermoelectric component.

11. The thermal interface of claim 8, wherein the thermal joint is a silicone pad.

12. The thermal interface of claim 1, wherein the first thermal component is a first shape at room temperature and a thermally deformed shape at an operating temperature of the thermal interface.

13. The thermal interface of claim 12, wherein the fluid filled cushion maintains thermal contact with said first thermal component while said thermal interface is at the operating temperature.

14. The thermal interface of claim 1, wherein said thermal interface is loaded via a loading component, and the loading component is compressible such that said second thermal component is maintained in thermal contact with said fluid filled cushion during operation of the thermal interface.

15. The thermal interface of claim 1, wherein said flexible outer wall comprises a plurality of inward facing protrusions extending from said flexible outer wall into said cavity.

16. A method for transferring heat comprising:
generating heat at a first thermal interface component such that a component of a heat transfer interface undergoes thermal deformation;
maintaining contact between a fluid filled cushion and said first thermal interface component during thermal deformation;
maintaining contact between a second thermal interface component and said fluid filled cushion such that a thermal pathway is provided from said first thermal interface component and said second thermal interface component.

17. The method of claim 16, wherein said second thermal interface component is a thermoelectric device and wherein passing heat through said second thermal interface components generates electrical energy.

18. The method of claim 16, wherein said first thermal interface component is an electronic component generating heat and said second thermal interface component is a heat sink.

19. The method of claim 16, wherein said step of maintaining contact between said fluid filled cushion and said first thermal interface component during thermal deformation comprises allowing a flexible wall of said fluid filled cushion to flex complimentary to said thermal deformation, thereby maintaining contact between said first thermal interface component and said second thermal interface component.

20. A waste heat recovery system for a turbine engine comprising:
a gas turbine engine component operable to generate waste heat;
a thermal interface connected to said gas turbine engine component, said thermal interface including a first thermal component, a second thermal component, a fluid filled cushion disposed between said first thermal component and said second thermal component, wherein said fluid filled cushion is a thermal joint, and wherein said second thermal component is a thermoelectric device.
